(19) United States
(12) Patent Application Publication
(10) Pub. No.: US 2025/0185368 A1
(43) Pub. Date: Jun. 5, 2025

(54) BACKSIDE CONTACT WITH EXTENSION REGION

(71) Applicant: INTERNATIONAL BUSINESS MACHINES CORPORATION, ARMONK, NY (US)

(72) Inventors: Min Gyu Sung, Latham, NY (US); Tao Li, Slingerlands, NY (US); Ruilong Xie, Niskayuna, NY (US); Eric Miller, Albany, NY (US)

(21) Appl. No.: 18/528,887

(22) Filed: Dec. 5, 2023

(51) Int. Cl. H01L 27/12

(52) U.S. Cl. CPC H10D 86/60; H10D 86/0214; H10D 86/441

(57) ABSTRACT

A backside contact includes an extension region and may further include an inline region. The inline region is below a source/drain region may the extension region extends horizontally generally underneath an adjacent source/drain region. The adjacent S/D region may be connected to a frontside back end of line (BEOL) network by a frontside contact. The extension region may provide for relatively increased surface area for a backside wire of a backside BEOL network to connect thereto, which may relatively decrease the interfacial resistance therebetween and which may ease alignment and/or landing complexities of the backside wire against the backside contact. The extension region may further allow for relatively increased backside wire pitch between backside wires of the backside BEOL network, which may reduce the propensity of shorting between the backside wires.

### BACKGROUND

A backside back-end-of-line (BEOL) network, such as a backside power distribution network (BSPDN) may include signal wires for signal routing and power wires for providing power potential (e.g., VDD, VSS, etc.). The backside BEOL network may allow for the distribution of power wires and signal wires between both the frontside and backside of the semiconductor IC device. The backside BEOL network may further allow for the full or partial decoupling of signal routing and/or power routing and/or allows for dividing or splitting power wires and/or signal wires between both the frontside and backside of the semiconductor IC device. By incorporating the backside BEOL network, routing congestion may be reduced, which may lead to further semiconductor integrated circuit (IC) device scaling. For example, semiconductor IC devices that incorporate a backside BEOL network can result in a 30% area reduction and improved current-resistance (IR) drop compared to typical semiconductor IC devices that include solely a frontside BEOL network.

However, the backside BEOL network may be difficult to manufacture as it requires structures of various microdevices, such as a transistor source, drain, and/or gate, to connect the backside wires of the backside BEOL network. Particularly, there are difficulties in providing for adequate electrical isolation between adjacent backside contacts, such as backside source/drain contacts, there are difficulties in providing for adequate electrical isolation between backside wires of the backside BEOL network that are connected to the adjacent backside contacts, or the like.

### SUMMARY

In an embodiment of the present disclosure, a semiconductor integrated circuit (IC) device is presented. The semiconductor IC device includes a backside back end of the line (BEOL) network comprising a backside wire. The semiconductor IC device further includes a first transistor that includes a first source/drain (S/D) region and a replacement placeholder below the first S/D region. The semiconductor IC device further includes a second transistor that includes a second source/drain (S/D) region and a backside contact connected to and below the second S/D region.

In an embodiment of the disclosure, another semiconductor integrated circuit (IC) device is presented. The semiconductor IC device includes a first transistor and a second transistor. The first transistor includes a first source/drain (S/D) region and a first backside contact connected to and below the first S/D region. The first backside contact includes a first inline region and a first extension region extending from the first inline region horizontally away from the second transistor. The second transistor includes a second source/drain (S/D) region and a second backside contact connected to and below the second S/D region. The second backside contact includes a second inline region and a second extension region extending from the second inline region horizontally away from the first transistor.

In yet another embodiment of the disclosure, a semiconductor integrated circuit (IC) device fabrication method is presented. The method includes forming a first backside contact placeholder and a second backside contact placeholder. The method includes forming a first source/drain (S/D) region upon the first backside contact placeholder and forming a second S/D region upon the second backside contact placeholder. The method includes removing the first backside contact placeholder while retaining the second backside contact placeholder. The method includes forming a replacement placeholder in place of the removed first backside contact placeholder. The method includes forming a backside contact opening within the replacement placeholder and by removing the second backside contact placeholder. The method further includes forming a backside contact within the backside contact opening. As a result, a backside contact that includes an extension region is formed. The extension regions may provide for relatively increased surface area for an applicable backside wire of a backside BEOL network to connect thereto, which may relatively decrease the interfacial resistance therebetween and which may ease alignment and/or landing complexities of the applicable backside wire against the backside contact. The extension region may further allow for relatively increased backside wire pitch which may reduce the propensity of shorting therebetween.

In an example, the backside contact further includes an inline region below the second S/D region. The extension region extends from the inline region such that a section of the extension region is surrounded by the replacement placeholder. Therefore, the replacement placeholder may adequately electrically isolate the extension region from the first S/D region there above.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts cross-section views of a semiconductor IC device that includes one or more backside contacts with respective extension regions, according to one or more embodiments of the disclosure.

FIG. 2 depicts a partial structure top-down view of a semiconductor IC device that includes one or more backside contacts with respective extension regions, according to one or more embodiments of the disclosure.

FIG. 3 through FIG. 14 depict various fabrication structure cross-section views of an illustrative semiconductor IC device that includes one or more backside contacts with respective extension regions, according to one or more embodiments of the disclosure.

FIG. 15 depicts a method of fabricating a semiconductor IC device that includes one or more backside contacts with respective extension regions, according to one or more embodiments of the disclosure.

### DETAILED DESCRIPTION

The embodiments of the present disclosure relate to fabrication methods and resulting structures for semiconductor devices. More specifically, the present disclosure relates to fabrication methods and resulting semiconductor integrated circuit (IC) devices that include one or more backside contacts with respective extension regions. In some examples, the extension region of the backside contact that is below a first source/drain region may extend underneath an adjacent source/drain region that is connected to a frontside back end of line (BEOL) network by a frontside contact. The extension region may provide for relatively increased surface area for a backside wire of the backside BEOL network to connect thereto, which may relatively decrease the interfacial resistance therebetween and which may ease alignment and/or landing complexities of the backside wire against the backside contact. The extension region may further allow for relatively increased backside wire pitch between backside wires of the backside BEOL network, which may reduce the propensity of shorting between the backside wires.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, e.g., source-drain current, is controlled by a voltage applied to an associated gate. A FET typically has three terminals, e.g., a gate structure, a source region, and a drain region. A gate structure is a structure used to control output current (e.g., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

For some transistors, integration of the transistors with a backside back-end-of-line (BEOL) network is one of the key challenges to providing increasing packaged IC device densities and performance increases. By incorporating a backside BEOL network into the semiconductor IC device, routing congestion may be eased. Currently, there is a need for semiconductor IC device fabrication techniques that include structures to adequately protect against shorting due to/from a backside contact.

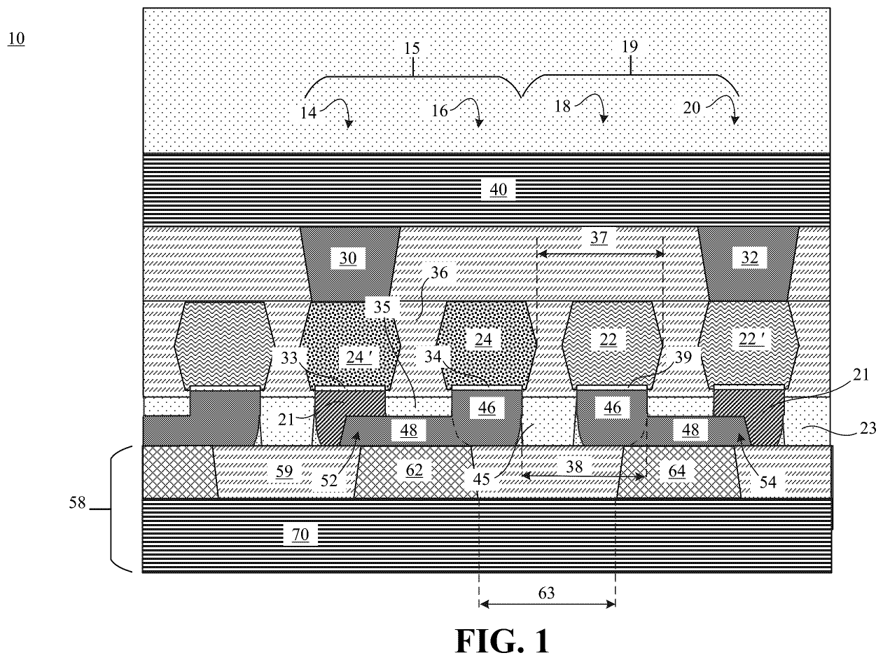

Referring now to FIG. 1, cross-sectional views of an illustrative semiconductor integrated circuit (IC) device 10 that includes adjacent backside contacts 52, 54 are depicted. Each backside contact 52, 54 includes an inline region 46 that is inline with a respective source/drain (S/D) region there above. For example, an inline region 46 of backside contact 52 may be inset within, underneath, and connected to a S/D region 24 there above and an inline region 46 of backside contact 54 may be inset within, underneath, and connected to a S/D region 22 there above.

Each backside contact 52, 54 includes an extension region 48 that extends from the inline region 46 substantially horizontally toward an adjacent S/D region, such that a least a portion of the extension region 48 is inset within and underneath the adjacent S/D region. For example, an extension region 48 of backside contact 52 extends from the inline region 46 substantially horizontally toward an adjacent S/D region 24′ such that a portion of the extension region 48 of backside contact 52 is inset within and underneath the adjacent S/D region 24′. Likewise, an extension region 48 of backside contact 54 extends from the inline region 46 substantially horizontally toward an adjacent S/D region 22′ such that a portion of the extension region 48 of backside contact 54 is inset within and underneath the adjacent S/D region 22′.

In examples, the adjacent S/D regions 22′, 24′ are connected to a frontside BEOL network 40 by a frontside contact 30, 32, respectively, and is also above a respective replacement placeholder 21 which is composed of a dielectric material. The replacement placeholder 21 may be formed within a cavity that is formed by the removal of a backside contact placeholder that is underneath the adjacent S/D region 22′, 24′, respectively. Because the adjacent S/D region 22′, 24′ is connected to the frontside BEOL network 40 by an associated frontside contact, the volume under the adjacent S/D region 22′, 24′ may be repurposed by the removal of the backside contact placeholder and by the formation of the replacement placeholder 21 in place thereof. In subsequent processing stages, the replacement placeholder 21 along with a backside interlayer dielectric (ILD) 23 may be subjected to an associated backside contact etch to form e.g., respective backside contacts 52, 54.

A backside BEOL network 58 may be formed upon the backside ILD 23 and upon the backside contacts 52, 54. The backside BEOL network 58 may include adjacent wires 62, 64. The respective extension regions 48 may provide for relatively increased surface area for an interface between the backside contact 52, 54 and the backside wire 62, 64, respectively. This relatively larger interfacial area may relatively decrease the interfacial resistance therebetween and may ease alignment complexities of the backside wires 62, 64 landing against the backside contact 52, 54, respectively. The respective extension regions 48 may further allow for relatively increased distance or pitch 63 between adjacent backside wires 62 and 64 of the backside BEOL network, which may reduce the propensity of shorting between the adjacent backside wires 62 and 64. For example, the relatively increased pitch 63 provides for increased isolative material, such as backside passivation material 59, between adjacent backside wires 62 and 64.

The S/D regions of semiconductor IC device 10 may be included within respective transistors 14, 16, 18, or 20. Transistors 14 and 16 may be included within a cell 15 and may share a respective gate that is around and that contacts each of a respective series of vertically stacked channels of transistor 14, 16. Respective first end surfaces of respective vertically stacked channels may be connected to the S/D region 24 and distal end surfaces of respective vertically stacked channels may be connected to another S/D region (located in a plane that exists into or out of the page). Similarly, respective first end surfaces of respective vertically stacked channels may be connected to the adjacent S/D region 24′ and distal end surfaces of respective vertically stacked channels may be connected to another S/D region (located in the plane that extends into or out of the page). In examples and as depicted, the S/D regions within the cell 15 may be of the same type (e.g., P-type or N-type) S/D regions.

Transistors 18 and 20 may be included within a cell 19 and may share a respective gate that is around and that contacts each of a respective series of vertically stacked channels of transistor 18, 20. Respective first end surfaces of respective vertically stacked channels may be connected to the S/D region 22 and distal end surfaces of respective vertically stacked channels may be connected to another S/D region (located in the plane that exists into or out of the page). Similarly, respective first end surfaces of respective vertically stacked channels may be connected to the adjacent S/D region 22′ and distal end surfaces of respective vertically stacked channels may be connected to another S/D region (located in the plane that exists into or out of the page). In examples and as depicted, the S/D regions within the cell 19 may be of the same type (e.g., P-type or N-type) S/D regions and may further be the opposite type relative to those S/D regions within cell 15.

For clarity, in a first embodiment, semiconductor IC device 10 includes a backside back end of the line (BEOL) network (e.g., backside BEOL network 58) that includes a backside wire (e.g., backside wire 62). The semiconductor IC device also includes a first transistor (e.g., transistor 14) comprising a first S/D region (e.g., adjacent S/D region 24′) and a replacement placeholder (e.g., replacement placeholder 21) below the first S/D region. The semiconductor IC device also includes a second transistor 16 comprising a second source/drain (S/D) region (e.g., S/D region 24) and a backside contact (e.g., backside contact 52) connected to and below the second S/D region. The backside contact includes an extension region (e.g., extension region 48) between the backside wire and the replacement placeholder. The extension region 48 may provide for relatively increased surface area for the backside wire 62 of the backside BEOL network 58 to connect thereto. This increased surface area may relatively decrease the interfacial resistance therebetween and may ease alignment and/or landing complexities of the backside wire 62 against the backside contact 52. The extension region 48 may further allow for relatively increased backside pitch 63 which may reduce the propensity of shorting of the backside wire 62 and backside wire 64 therebetween.

In an example, the first transistor and the second transistor are in a same transistor cell (e.g., cell 15). For example, the first transistor and the second transistor are in a same complementary metal oxide semiconductor (CMOS) cell in which the first transistor and the second transistor both have either p-type or n-type S/D regions. Therefore, as the first transistor and the second transistor may are within the same cell, they may share transistor structures, such as a common gate, or the like.

In an example, the first S/D region and the second S/D region are directly adjacent. This results in the extension region extending underneath an adjacent S/D region, as opposed to extending underneath multiple S/D regions. In this example, the ILD 36 may directly contact a sidewall of the first S/D region and may directly contact the second S/D region. This may further result in the extension region 48 being located generally between and underneath both the first S/D region and the second S/D region.

In an example, the backside wire (e.g., backside wire 62) is directly connected to the extension region (e.g., extension region 48). As a result, the extension region 48 resides between and underneath both the first S/D region and the second S/D region, which may allow for backside wire 62 and backside wire 64 to be spaced relatively further away from one another, which may decrease the propensity of electrical shorting there between.

In an example, the backside contact further includes an inline region (e.g., inline region 46) that is substantially inline with and below (e.g., inset within and underneath) the second S/D region (e.g., S/D region 24) and from which the extension region (e.g., extension region 48) horizontally extends toward the replacement placeholder (e.g., replacement placeholder 21). As such, the inline region 46 is directly below and inset within the second S/D region 24 and may be structurally integral with the extension region 48, as opposed to being separate structures, materials, or the like, that would add interfacial resistance therebetween.

In an example, the replacement placeholder (e.g., replacement placeholder 21) electrically isolates the extension region (e.g., extension region 48) from the first S/D region (e.g., adjacent S/D region 24′). The material of the replacement placeholder 48 may be chosen to achieve predetermined dielectric properties to prevent or mitigate electrical shorting between the extension region 48 and the adjacent S/D region 24′ there above.

The semiconductor IC device 10 may further include a frontside BEOL network (e.g., frontside BEOL network 40) and a frontside contact (e.g., frontside contact 30) that connects the first S/D region (e.g., adjacent S/D region 24′) to the frontside BEOL network. Because the adjacent S/D region 24′ is connected from its frontside to the frontside BEOL network, the area below the adjacent S/D region 24′ may be unutilized or otherwise open, allowing the extension region 48 to extend thereunder.

In an example, the first transistor (e.g., transistor 14) includes a first etch stop (e.g., etch stop 33) between the first S/D region (e.g., adjacent S/D region 24′) and the replacement placeholder (e.g., replacement placeholder 21) and the second transistor includes a second etch stop (e.g., etch stop 34) between the second S/D region (e.g., S/D region 24) and the inline region (e.g., inline region 46). The etch stop 33 may be utilized to selectively remove an associated backside contact placeholder 62 that forms a cavity in which the replacement placeholder 21 may be formed. Similarly, the second etch stop 34 may be utilized to selectively remove an associated backside contact placeholder 62 that forms another cavity in which the inline region 46 may be formed.

In an example, a shallow trench isolation (STI) region (e.g., STI region 35) is between the inline region (e.g., inline region 46) and the replacement placeholder (e.g., replacement placeholder 21). As a result, a top surface of the extension region 48 may be below a top surface of the STI region 35.

For clarity, in a second embodiment, semiconductor IC device 10 includes a first transistor (e.g., transistor 16) and a second transistor (e.g., transistor 18). The first transistor includes a first source/drain (S/D) region (e.g., S/D region 24) and a first backside contact (e.g., backside contact 52) connected to and below the first S/D region. The first backside contact includes a first inline region (e.g., inline region 46 of backside contact 52) and a first extension region (e.g., extension region 48 of backside contact 52) extending from the first inline region horizontally away from the second transistor. The second transistor includes a second source/drain (S/D) region (e.g., S/D region 22) and a second backside contact (e.g., backside contact 54) connected to and below the second S/D region. The second backside contact includes a second inline region (e.g., inline region 46 of backside contact 54) and a second extension region (e.g., extension region 48 of backside contact 54) extending from the second inline region horizontally away from the first transistor. The extension regions may provide for relatively increased surface area for an applicable backside wire 62, 64 of a backside BEOL network 70 to connect thereto, which may relatively decrease the interfacial resistance therebetween and which may ease alignment and/or landing complexities of the applicable backside wire 62, 64 against the backside contact 52, 54. The extension regions may further allow for relatively increased backside wire 62, 64 pitch 63 which may reduce the propensity of shorting therebetween.

In an example, the first transistor (e.g., transistor 16) is a pFET and the second transistor (e.g., transistor 18) is an nFET. For example, the first transistor and the second transistor are in different complementary metal oxide semiconductor (CMOS) cells and the first S/D region 24 and the second S/D region 22 may be directly adjacent which results in the respective extension regions 48 of the backside contact 52, 54 extending in relatively opposing horizontal directions away from one another.

In an example, an interlayer dielectric (e.g., ILD 36) is between sidewall(s) of the first S/D region (e.g., S/D region 24) and sidewall(s) of the second S/D region (e.g., S/D region 22). In this example, the ILD 36 may directly contact a sidewall of the first S/D region and may directly contact the second S/D region. This may further result in the pitch 37 between the S/D region 24 and the S/D region 22 to be relatively reduced, compared to other S/D regions with backside contacts without extension regions, which may enable further semiconductor IC device scaling.

In an example, semiconductor IC device further includes a backside back end of the line (BEOL) network (e.g., backside BEOL network 58) comprising a first backside wire (e.g., backside wire 62) below and connected to the first extension region (e.g., extension region 48 of backside contact 52) and a second backside wire (e.g., backside wire 64) below and connected to the second extension region (e.g., extension region 48 of backside contact 54). The extension regions 48 may provide for relatively increased surface area for an applicable backside wire 62, 64 to connect thereto, which may relatively decrease the interfacial resistance therebetween and which may ease alignment and/or landing complexities of the backside wire 62, 64 against the backside contact 52, 54. The extension regions 48 may further allow for relatively increased backside wire 62, 64 pitch 63 which may reduce the propensity of shorting therebetween.

In an example, the first inline region (e.g., inline region 46 of backside contact 52) is substantially inline with and below (e.g., inset within and underneath) the first S/D region (e.g., S/D region 24) and wherein the second inline region (e.g., inline region 46 of backside contact 54) is substantially inline with and below the second S/D region (e.g., S/D region 22). As such, the first inline region is directly below and inset within the first S/D region. This may be the result of the inline region 46 being formed by filling a cavity formed by the removal of a backside contact placeholder which was utilized to form the first S/D region. Similarly, the second inline region is directly below and inset within the second S/D region. This may be the result of the inline region 46 being formed by filling a cavity formed by the removal of a backside contact placeholder which was utilized to form the second S/D region.

In an example, a pitch (e.g., pitch 63) between the first backside wire (e.g., backside wire 62) and the second backside wire (e.g., backside wire 64) is greater than a pitch (e.g., pitch 37) between the first S/D region (e.g., S/D region 24) and the second S/D region (e.g., S/D region 22). Therefore, routing complexities from the backside of the first S/D region 24 and the S/D region 22 to, for example, the backside BEOL network 70, may be reduced.

In an example, a pitch (e.g., pitch 63) between the first backside wire (e.g., backside wire 62) and the second backside wire (e.g., backside wire 64) is greater than a pitch (e.g., pitch 38) between the first inline region (e.g., inline region 48 of backside contact 52) and the second inline region (e.g., inline region 48 of backside contact 54). As the pitch 63 is larger than the pitch 38, routing complexities from the backside of the first S/D region 24 and the S/D region 22 to, for example, the backside BEOL network 70, may be reduced.

In an example, the first transistor (e.g., transistor 16) comprises a first etch stop (e.g., etch stop 34) between the first S/D region (e.g., S/D region 24) and the first inline region (e.g., inline region 48 of backside contact 52) and wherein the second transistor (e.g., transistor 18) comprises a second etch stop (e.g., etch stop 39) between the second S/D region (e.g., S/D region 22) and the second inline region e.g., inline region 48 of backside contact 54). The first etch stop 34 and the second etch stop 39 may be retained and may be utilized to remove an associated backside contact placeholder that forms respective cavities in which the first and second inline portions may be formed, respectively.

In an example, a shallow trench isolation (STI) region (e.g., STI region 45) is between the first inline region (e.g., inline region 48 of backside contact 52) and the second inline region (e.g., inline region 48 of backside contact 54). Therefore, the first inline region and the second inline region be directly adjacent and with the STI region 45 horizontally therebetween which results in the extension regions 48 extending in an opposing horizontal direction relatively thereto.

In yet another embodiment of the disclosure, a semiconductor integrated circuit (IC) device fabrication method is presented. The method includes forming a first backside contact placeholder and a second backside contact placeholder. The method includes forming a first source/drain (S/D) region upon the first backside contact placeholder and forming a second S/D region upon the second backside contact placeholder. The method includes removing the first backside contact placeholder while retaining the second backside contact placeholder. The method includes forming a replacement placeholder in place of the removed first backside contact placeholder. The method includes forming a backside contact opening within the replacement placeholder and by removing the second backside contact placeholder. The method further includes forming a backside contact within the backside contact opening. As a result, a backside contact that includes an extension region is formed. The extension regions may provide for relatively increased surface area for an applicable backside wire of a backside BEOL network to connect thereto, which may relatively decrease the interfacial resistance therebetween and which may ease alignment and/or landing complexities of the applicable backside wire against the backside contact. The extension region may further allow for relatively increased backside wire pitch which may reduce the propensity of shorting therebetween.

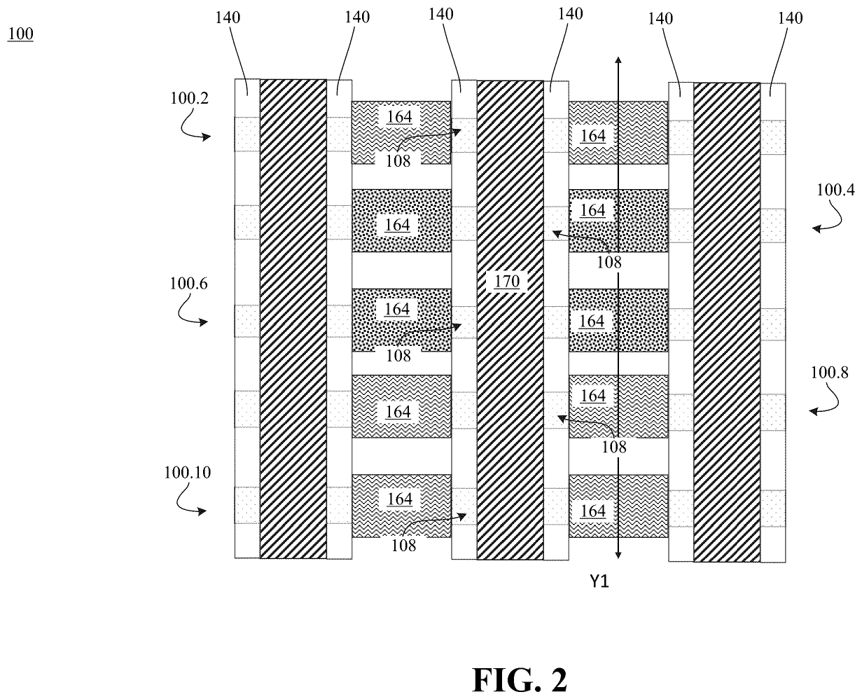

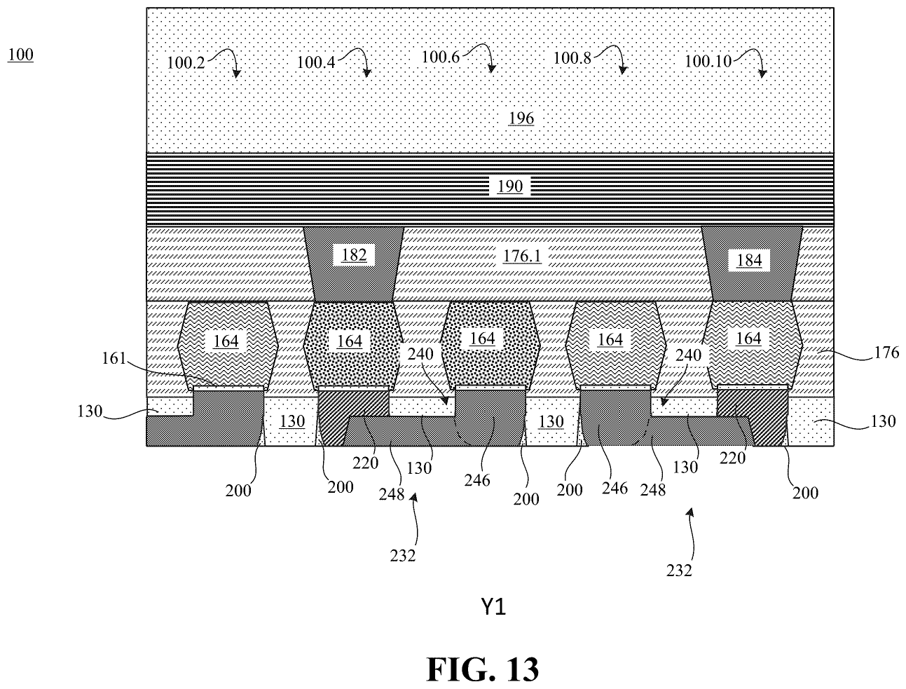

FIG. 2 depicts a partial structural top-down view of a semiconductor IC device 100 that is to include one or more backside contacts 240, as are illustratively depicted in FIG. 13, according to one or more embodiments of the disclosure. Semiconductor IC device 100 includes transistors 100.2, 100.4, 100.6, 100.8, and 100.10. Each transistor 100.2, 100.4, 100.6, 100.8, and 100.10 may include a series of vertically stacked channels (e.g., a plurality of active semiconductor nanolayers 108 vertically stacked in various planes into and/or out of the page) between a respective source and/or drain (S/D) region (e.g., S/D regions 164). Transistors 100.2, 100.4, 100.6, 100.8, and 100.10. may share a replacement gate structure 170 that includes a conductive gate that is around and that contacts each of a series of vertically stacked channels of transistors 100.2, 100.4, 100.6, 100.8, and 100.10. A gate spacer 140 may contact and be against the replacement gate structure 170. An inner spacer may be located underneath the gate spacer and between adjacent vertically stacked channels and may adequately prevent shorting of the conductive gate with the S/D regions. In examples and as depicted, the S/D regions 164 within the transistors 100.2, 100.8, and 100.10 may be of the same type and the S/D regions 164 within the transistors 100.4, 100.6 may be of the same type and may further be the opposite type relative to those S/D regions 164 within the transistors 100.2, 100.8, and 100.10.

FIG. 2 also depicts a location of cross-sectional plane Y1, a vertical plane located between adjacent replacement gate structures 170 across various S/D region 164 of the transistors 100.2, 100.4, 100.6, 100.8, and 100.10.

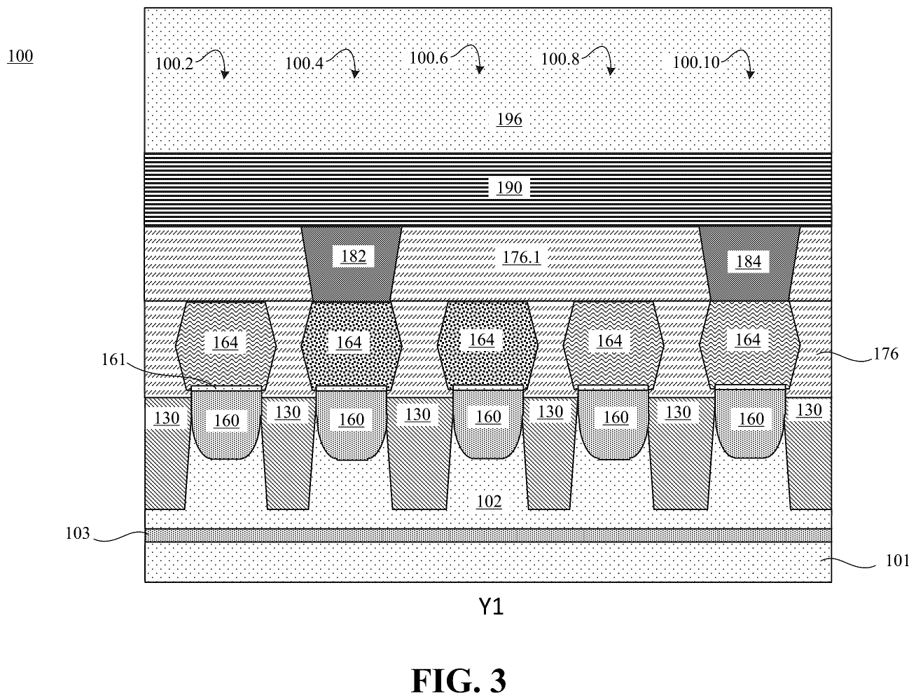

FIG. 3 depicts a cross-sectional view of a semiconductor IC device 100 that is to include one or more backside contacts 240, as are illustratively depicted in FIG. 13, according to one or more embodiments of the disclosure. At this initial fabrication stage, the semiconductor IC device 100 may include a lower substrate 101, an etch stop layer 103, an upper substrate 102, STI regions 130, backside contact placeholders 160, etch stop layers 161, S/D regions 164, a frontside ILD 176, a frontside contact ILD 176.1, a frontside contact 182, a frontside contact 184, a frontside BEOL network 190, and a carrier wafer 196.

For clarity, various background fabrication stages are described below that may be used to form the depicted semiconductor IC device 100. These background fabrication stages may reference structures that are not shown in the present cross-section Y1 but descriptions of the formation thereof are included herein to more fully enable the illustrated semiconductor IC device 100.

The illustrative semiconductor IC device 100 may be formed by initially providing or forming a substrate structure. The substrate structure may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In the depicted implementation, the substrate structure includes an upper substrate 102, a lower substrate 101, and an etch stop layer 103 between the upper substrate 102 and the lower substrate 101. The upper substrate 102 and the lower substrate 101 may be comprised of any suitable material(s) including those listed above, and the etch stop layer 103 may be a dielectric material with etch selectivity to one or both of the upper substrate 102 and/or the lower substrate 101. In one example, the etch stop layer 103 may be an oxide and the substrate structure may be referred to as a buried oxide (BOX) substrate. In another example, the lower substrate 101 may be composed of Si. The etch stop layer 103 may be composed of Silicon Germanium (SiGe) and may be epitaxially grown from the top surface of lower substrate 101 and the upper substrate 102 may be composed of Si and may be epitaxially grown from the top surface of etch stop layer 103.

Next, the illustrative semiconductor IC device 100 may be formed by forming nanolayers over the substrate structure by forming a bottommost sacrificial nanolayer (not shown) and by forming a series of alternating sacrificial nanolayers (not shown) and active nanolayers 108, shown at a later stage of fabrication in FIG. 2, thereupon. In certain examples, the bottommost sacrificial nanolayer is initially formed directly on an upper surface of the substrate structure. In other examples, certain layer(s) may be formed between the upper surface of the substrate structure and the bottommost sacrificial nanolayer. In an example, the bottommost sacrificial nanolayer may be formed by epitaxially growing a SiGe layer with a relatively high percentage of Ge, ranging from 50% to 70%. The bottommost sacrificial nanolayer may have etch selectivity relative to the sacrificial nanolayers and active nanolayers 108.

The nanolayers may be further formed by fabricating the alternating series of sacrificial nanolayers, such as SiGe sacrificial nanolayers, and active nanolayers 108, such as Si nanolayers, upon the bottommost sacrificial nanolayer. The sacrificial nanolayers can have Ge percentages ranging from 20% to 45%. In an implementation, the alternating active sacrificial nanolayer and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

It should be appreciated that any suitable number of alternating nanolayers may be formed. Although it is specifically contemplated that the bottommost sacrificial nanolayer and the sacrificial nanolayers can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottommost sacrificial nanolayer, the sacrificial nanolayers, and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

In certain embodiments, the nanolayers have a vertical thickness ranging, for example, from approximately 3 nm to approximately 20 nm. In certain embodiments, the nanolayers have a vertical thickness ranging, for example, from approximately 3 nm to approximately 10 nm. Although the range of 3-20 nm is cited as an example range of thickness of the nanolayers, other thickness of these nanolayers may be used. In certain examples, certain of the nanolayers may have different thicknesses relative to one another. In certain examples, it may be desirable to have a small vertical spacing (VSP) between adjacent active nanolayers 108 to reduce the parasitic capacitance and to improve circuit speed. For example, the VSP (the distance between vertically adjacent active nanolayers 108) may range from 5 nm to 15 nm. However, the VSP must be of a sufficient value to accommodate the formation of a gate that is to be formed in the spaces created by later removal of respective portions of the sacrificial nanolayers.

Further, in the depicted fabrication stages, the nanolayers may be patterned into nanolayer stacks (not shown) and shallow trench isolation (STI) regions 130, shown for example in FIG. 3 may be formed.

To form one or more nanolayer stacks, a mask layer (not shown) may be formed on the uppermost nanolayer. The mask layer may be comprised of any suitable mask material(s). The mask layer may be patterned and used to perform the nanolayer stack patterning process. In the nanolayer stack patterning process, any suitable material removal process (e.g., reactive ion etching or RIE) may be used to remove portions of the alternating nanolayers down to the level of the substrate structure, or the like. Following the nanolayer stack patterning process, the one or more nanolayer stacks are formed. Subsequently, the mask layer may be removed.

The removal of undesired portion(s) of the alternating nanolayers may further remove undesired portions of substrate structure that are adjacent to respective footprints of nanolayer stacks to form STI region openings. The etch may be timed or otherwise controlled to stop the removal of the substrate structure such that the depth or bottom of the one or more STI region openings has a predetermined or desired dimension. For example, the depth or bottom of the one or more STI region openings may be above the etch stop layer 103, as depicted. In some examples, the etch to form the nanolayer stacks may utilize the etch stop layer 103 to stop the etch and form the bottom well of the one or more STI region openings.

A STI region 130 may be formed upon and/or within the substrate structure within respective STI region openings. The STI regions 130 may be formed by depositing electrical dielectric material(s) within respective STI region opening(s) that are adjacent to the one or more nanolayer stacks. A top surface of the one or more STI regions 130 may be initially coplanar with or below a top surface of the substrate structure. In some implementations, further fabrication operations may generally remove portions of the STI regions 130 (e.g., sacrificial gate removal, replacement gate fabrication pre-clean, etc.), such that the top surfaces of the STI regions 130 are below the top surface of the substrate structure.

The one or more STI regions 130 may have a volume and/or geometry that sufficiently electrically isolates components or features of neighboring transistors 100.2, 100.4, 100.6, 100.8, and 100.10, or the like, may sufficiently electrically isolate neighboring nanolayer stacks. For clarity, a particular STI region 130 may separate and adequately electrically isolate neighboring transistors 100.2, 100.4.

In an example, the STI region(s) 130 may be formed by depositing a STI liner within the STI region openings. Subsequently, STI region(s) 130 may be further formed by depositing STI dielectric material upon the STI liner. A etch back, recess, or the like, may occur to remove undesired or over formed STI liner and/or STI dielectric material, such that the top surface of the STI region(s) 130 are coplanar with or below a bottom surface of the bottommost sacrificial nanolayer. STI liner may be composed of but not limited to a nitride, low-K nitride (e.g., a nitride material with a lower dielectric constant relative to SiO₂), or the like. The STI dielectric material may be composed of but not limited to an oxide, low-K oxide (e.g., an oxide material with a lower dielectric constant relative to SiO₂), or the like. For clarity, as the STI regions 130 are formed within the substrate structure upon which the transistors 100.2, 100.4, 100.6, 100.8, and 100.10, are to be formed, the STI regions 130 may generally be located below or underneath the transistor layer or level.

The illustrated semiconductor IC device 100 may be further fabricated by next forming sacrificial gate structures (not shown). The sacrificial gate structures may include a sacrificial gate liner, a sacrificial gate, and a sacrificial gate cap. The sacrificial gate structures may be formed by initially depositing a sacrificial gate liner layer (e.g., a dielectric, oxide, or the like) upon the one or more STI regions 130 and upon and around the one or more nanolayer stacks. The sacrificial gate structures may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer stacks. The sacrificial gate structures may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner, the sacrificial gate, and the sacrificial gate cap, respectively, of each of the one or more sacrificial gate structures.

One or more sacrificial gate structures can be formed on targeted regions or areas of semiconductor IC device 100 to define the length of one or more GAA FETs and to provide sacrificial material for yielding targeted GAA FET structure(s) in subsequent processing.

The illustrated semiconductor IC device 100 may be further fabricated by next removing the bottommost sacrificial nanolayer. The bottommost sacrificial nanolayer may be removed by a wet etch utilizing an etchant that targets the material of the bottommost sacrificial nanolayer selective to the respective material(s) of the sacrificial nanolayers, the active nanolayers 108, the STI region(s) 130, and/or sacrificial gate structures, as appropriate. The etch may be timed or otherwise controlled to effectively remove the bottommost sacrificial nanolayer while substantially retaining the sacrificial nanolayers, the active nanolayers 108, the STI region(s) 130, and the sacrificial gate structures, etc. The removal of bottommost sacrificial nanolayer may form a bottom isolation cavity between the substrate structure and the lowest sacrificial nanolayer.

The illustrated semiconductor IC device 100 may be further fabricated by next forming gate spacers 140, shown in FIG. 2, and a bottom isolation (not shown) in place of the removed bottommost sacrificial nanolayer within the nanolayer stacks. The gate spacer(s) 140 may be formed upon the sidewall(s) of the sacrificial gate structures, upon the STI region(s) 130, and around the one or more nanolayer stacks.

The bottom isolation and the gate spacer(s) 140 may be simultaneously formed by a conformal deposition of a dielectric material, such as silicon nitride, SiBCN, SiNC, SiN, SiCO, SiNOC, or a combination thereof, or the like, within the nanolayer cavity(ies), upon STI regions 130, upon around the one or more sacrificial gate structures, and upon and around the one or more nanolayer stack(s). Subsequently, undesired portions of dielectric material may be removed while desired portions the dielectric material may be retained and thereby form the bottom isolation and the gate spacer(s) 140. The undesired portions of dielectric material may be removed by a directional ion etch, such as a reactive ion etch (RIE). The RIE may remove exposed or unprotected horizontal portions of the dielectric material while retaining protected horizontal portions of the dielectric layer (e.g., the bottom isolation) and vertical portions of the dielectric layer (e.g., the gate spacer(s) 140).

For clarity, semiconductor IC device 100, can also be fabricated by operations that do not remove the bottommost sacrificial nanolayer to form the associated bottom isolation cavity to allow the formation of both gate spacer(s) 140 and the bottom isolation. Rather, such semiconductor devices may retain the bottommost sacrificial nanolayer while the gate spacer(s) 140 are formed. This bottommost sacrificial nanolayer may be removed during the removal of the sacrificial nanolayers and the bottom isolation may be formed along with the inner spacers (not shown).

The illustrated semiconductor IC device 100 may be further fabricated by next forming source/drain (S/D) recesses (not shown) within the one or more nanolayer stacks between gate spacers 140 of neighboring sacrificial gate structures. In other words, a single nanolayer stack may be separated, by one or more S/D recesses, into multiple nanolayer stacks each located underneath at a portion of respective sacrificial gate structures and associated gate spacers 140.

The one or more S/D recesses may be formed between adjacent sacrificial gate structures by removing respective portions of the sacrificial nanolayers and active nanolayers 108 that are between gate spacers 140 of adjacent or neighboring sacrificial gate structures. The one or more S/D recesses may be formed to a depth to stop at the top surface of the substrate structure (e.g., the top surface of upper substrate 102, or the like), the top surface of STI regions 130, or the like. Alternatively, the one or more S/D recesses may be formed to a depth within the upper substrate 102 above the etch stop layer 103 so that backside contact placeholder(s) 160 may be formed generally below a respective S/D region 164.

The undesired portions of sacrificial nanolayers, active nanolayers 108, and the like, may be removed by etching or other subtractive removal techniques. The top surface of the substrate structure may be used as an etch stop or other etch parameters may be controlled to stop the material removal at the substrate structure. As the gate spacers 140 and the sacrificial gate structures may be utilized to protect the underlying portions of sacrificial nanolayers, active nanolayers 108, and bottom isolation (if present), respective sidewalls of the nanolayer stacks may be substantially coplanar and substantially vertical with the outer sidewalls of the gate spacers 140 there above.

As used herein, “substantially vertical” sidewalls deviate from a direction normal to a major surface (e.g., top surface, etc.) of the substrate 102 by less than 5°, e.g., 0°, 1°, 2°, 3°, 4°, or 5°, including ranges between any of the foregoing values.

The illustrated semiconductor IC device 100 may be further fabricated by next forming horizontal or lateral indents by laterally or horizontally removing respective portions of sacrificial nanolayers within the nanolayer stacks. The indents may be formed by a reactive ion etch (RIE) process, which can remove portions of the sacrificial nanolayers. The horizontal depth of the indents may be chosen to set a length for a replacement gate structure 170, shown in FIG. 2, that is formed in place of one sacrificial gate structure. When the sacrificial nanolayers are composed of SiGe and when active nanolayers 108 are Si, the directional RIE can use a boron-based chemistry or a chlorine-based chemistry, for example, which recesses or removes the exposed end portions of sacrificial nanolayers (e.g., end portions of sacrificial nanolayers generally below spacer 140) selective to the Si active nanolayers 108. In alternative implementations when sacrificial nanolayers are not SiGe and when active nanolayers 108 are not Si, the directional etch of the sacrificial nanolayers may generally be selective to the active nanolayers 108, gate spacers 140, STI regions 130, and/or substrate structure.

The illustrated semiconductor IC device 100 may be further fabricated by next forming a respective inner spacer (not shown) within each indent. The one or more inner spacers 144 can be formed by ALD or CVD or any other suitable deposition technique that deposits a dielectric material within the indent(s), thereby forming the inner spacer(s). In some examples, the inner spacer(s) are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacer(s), an isotropic etch process is performed to create substantially vertical sidewalls of the inner spacer(s) that are coplanar with the substantially vertical sidewalls of the active nanolayers 108, of the gate spacers 140, and/or of the bottom isolation.

The illustrated semiconductor IC device 100 may be further fabricated by next forming one or more backside contact placeholders 160 within the substrate structure in between adjacent sacrificial gate structures within a respective S/D recess. In one example, a respective backside contact placeholder 160 may be formed in all location(s) such that a respective backside contact placeholder 160 is located underneath each S/D region 164.

If the S/D recesses are not of sufficient depth, the one or more backside contact placeholders 160 may be formed by initially forming one or more backside contact placeholder cavities within the substrate structure generally in between adjacent sacrificial gate structures and below the prior respective one or more S/D recesses. For example, the one or more backside contact placeholder(s) cavities may be formed by a subtractive removal technique, such as an etch, that removes associated portion(s) of the upper substrate 102. The etch may be timed or otherwise controlled to stop the removal of the upper substrate 102 such that the depth or bottom of the one or more backside contact placeholder(s) cavities are above the etch stop layer 103.

The one or more backside contact placeholders 160 may be further formed by epitaxially growing an epitaxial material from exposed substrate structure surface(s) within the one or more backside contact placeholder(s) cavities. In some embodiments, epitaxial growth and/or deposition processes may be selective to forming on the semiconductor surfaces of the upper substrate 102, and may not deposit material on dielectric surfaces, such as silicon dioxide or silicon nitride surfaces. In some embodiments, the epitaxial growth of the one or more backside contact placeholders 160 may overgrow above the top surface of the substrate structure or above the top surface of bottom isolation. In an example, the epitaxial material of the one or more backside contact placeholders 160 may be chosen to be etch selective to the material of the S/D region(s) 164, the material of the upper substrate 102, or the like. In another example, an etch stop layer 161 (e.g., a Si epitaxially grown layer, or the like) may be formed upon the top surface of the backside contact placeholders 160. For example, the one or more backside contact placeholders 160 may be SiGe and a Si etch stop layer 161 may be epitaxially grown from the top surface of the SiGe backside contact placeholders 160. Respective top surfaces of the backside contact placeholders 160 (or etch stop layer 161 thereupon) may be substantially horizontal and below the bottom surface of the bottommost active nanolayer 108 (e.g., to enable contact between such active nanolayer 108 and the S/D region 164) and/or substantially coplanar with a respective one or more top surface(s) of bottom isolation.

The illustrated semiconductor IC device 100 may be further fabricated by next forming a respective S/D region 164 upon a respective backside contact placeholder 160. Each S/D region 164 may form either a source or a drain, respectively, of respective transistors 100.2, 100.4, 100.6, 100.8, and 100.10, and is connected to respective end surface of the active nanolayers 108 of a nanolayer stack. Each S/D region 164 is composed of a semiconductor material and a dopant. As used herein, a “source/drain” region can be a source region or a drain region depending on subsequent wiring and application of voltages during operation of the applicable transistor. The semiconductor material that provides each of the S/D regions 164 may be composed of one of the semiconductor materials mentioned above for the semiconductor structure. For example, the semiconductor material that provides the S/D region 164 can be compositionally the same, or compositionally different from each active nanolayer 108. The dopant that is present in the S/D region 164 can be either a p-type dopant or an n-type dopant. The term “p-type” refers to the addition of impurities to an intrinsic semiconductor that creates deficiencies of valence electrons. In a silicon-containing semiconductor material, examples of p-type dopants, e.g., impurities, include, but are not limited to, boron, aluminum, gallium, phosphorus, and indium. “n-type” refers to the addition of impurities that contributes free electrons to an intrinsic semiconductor. In a silicon containing semiconductor material, examples of n-type dopants, include, but are not limited to, antimony, arsenic and phosphorous. In one example, each of the S/D region 164 can have a dopant concentration of from 4×10²⁰ atoms/cm³ to 3×10²¹ atoms/cm³.

The one or more S/D regions 164 may be epitaxially grown or formed. In some examples, the S/D region 164 are formed by in-situ doped epitaxial growth. The use of an in-situ doping process is merely an example. For instance, one may instead employ an ex-situ process to introduce dopants into the S/D regions 164. Other doping techniques can be used to incorporate dopants in the S/D regions 164. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions that promote in-situ Boron doped SiGe for p-type transistor and phosphorus or arsenic doped silicon or Si:C for n-type transistors.

In some examples, the epitaxial growth that forms the S/D region 164 occurs or is promoted from the top surface of upper substrate 102, from the upper surface of backside contact placeholders 160 (or etch stop layer 161 thereupon), or the like, while epitaxial growth may be limited or does not occur from neighboring STI regions 130.

In some embodiments, epitaxial growth to form the one or more S/D regions 164 may overgrow above the upper surface of the sacrificial gate structure(s) and be subsequently recessed such that the top surface of the S/D region 164 may be substantially horizontal and above the top surface of the topmost active nanolayer 108 within the nanolayer stacks (e.g., to enable contact between the end surface of that active nanolayer 108 and the S/D region 164).

The illustrated semiconductor IC device 100 may be further fabricated by next forming interlayer dielectric (ILD) 176. For example, a blanket ILD 176 may be deposited over the S/D region(s) 164, over the STI region(s) 130, over the sacrificial gate structures, and over the gate spacers 140, and the like.

The ILD 176 can be any suitable material, such as, for example, porous silicates, carbon doped oxides, silicon dioxides, silicon nitrides, silicon oxynitrides, OPL, or other dielectric materials. Any known manner of forming the ILD 176 can be utilized. The ILD 176 can be formed using, for example, CVD, PECVD, ALD, flowable CVD, spin-on dielectrics, or PVD.

In an example, the ILD 176 may be formed to a thickness above the top surface of the sacrificial gate structures. Subsequently, a planarization process, such as a CMP, may be performed to remove excess ILD 176 material and to remove the sacrificial gate caps of the sacrificial gate structures, thereby exposing the sacrificial gate thereunder. The planarization may also partially remove some of the sacrificial gates or may at least expose the sacrificial gate of the sacrificial gate structures. The CMP may create a substantially planar or substantially horizontal top surface for the semiconductor IC device 100. In other words, the respective top surfaces of ILD 176, gate spacers 140, sacrificial gates, S/D regions 164, etc. may be substantially coplanar and/or substantially horizontal.

The illustrated semiconductor IC device 100 may be further fabricated by next removing the sacrificial gate structures and then forming replacement gate structures 170 in place thereof. The sacrificial gate structures may be removed by initially removing the sacrificial gate and sacrificial gate oxide by a removal technique, such as one or more series of etches. For example, such removal may be accomplished by a wet chemical etching process in which one or more chemical etchants are used to remove the sacrificial gate and sacrificial gate oxide of the sacrificial gate structures. Appropriate etchants may be used that remove the sacrificial gate and/or sacrificial gate oxide selective to the active nanolayers 108, inner spacers, gate spacers 140, the bottom isolation, STI regions 130, or the like. For clarity, the removal of the sacrificial gate structure may further remove the sacrificial gate, sacrificial gate oxide, or the like.

Next, or simultaneously, the active nanolayers 108 may be released by removing the sacrificial nanolayers within the nanolayer stacks. The sacrificial nanolayers may be removed by a removal technique, such as one or more series of etches. For example, the etching can include a wet chemical etching process in which one or more chemical etchants are used to remove the sacrificial nanolayers. Appropriate etchants may be used that remove the sacrificial nanolayers selective to the active nanolayers 108, inner spacers, the bottom isolation, gate spacers 140, or the like. After the removal of sacrificial nanolayers, void spaces may be formed above and/or below the active nanolayers 108.

The illustrated semiconductor IC device 100 may be further fabricated by next forming a replacement gate structure 170 in place of the removed sacrificial gate structures around the active nanolayers 108, upon STI region(s) 130, upon the bottom isolation, etc.

Replacement gate structure(s) 170 may be formed by initially forming an interfacial layer on the gate spacers 140, on the active nanolayers 108, on the bottom isolation, on the inner spacers, etc. that are interior to and/or upon the respective surfaces interior to the opening created by the removal of the sacrificial gate structure and the releasing of the active nanolayers 108. The interfacial layer can be deposited by any suitable techniques, such as ALD, CVD, PVD, thermal oxidation, combinations thereof, or other suitable techniques.

Replacement gate structure(s) 170 may be further formed by forming a high-k layer to cover the exposed surfaces of the interfacial layer. The high-layer can be deposited by any suitable techniques, such as ALD, CVD, metal-organic CVD (MOCVD), PVD, thermal oxidation, combinations thereof, or other suitable techniques. A high-K material is a material with a higher dielectric constant than that of SiO₂, and can include e.g., LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The high-κ layer can include a single layer or multiple layers, such as metal layer, liner layer, wetting layer, and adhesion layer. In other embodiments, the high-K layer can include, e.g., Ti, Ag, Al, TiAlN, TaC, TaCN, TaSiN, Mn, Zr, TiN, TaN, Ru, Mo, Al, WN, Cu, W, or any suitable materials.

Replacement gate structure(s) 170 may be further formed by depositing a work function (WF) gate upon the high-K layer. The WF gate can be comprised of a conductor or metal, such as, e.g., copper (Cu), cobalt (Co), aluminum (Al), platinum (Pt), gold (Au), tungsten (W), titanium (Ti), nitride (N³⁻) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the device. The high-κ layer may separate the WF gate from the nanolayer channel (e.g., active nanolayer 108). Other metals that may be desired to further fine tune the effective work function (eWF) and/or to achieve a desired resistance value associated with current flow through the gate in the direction parallel to the plane of the nanolayer channel.

The one or more replacement gate structure(s) 170 may be further formed by depositing a conductive gate. In an example, when none of the previous replacement gate material(s) are utilized in the replacement gate structures 170, the conductive gate may be formed upon the same or similar surfaces as those upon which the interfacial layer, described above, may be formed. In other examples, when one or more of the interfacial layer, the high-K layer, the WF gate, or the like, are utilized in the replacement gate structures, the conductive gate may be formed upon the most recent structural formation thereof.

The conductive gate can be comprised of a conductor material and/or metal, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP, mechanical grinding process, or the like. After the planarization technique, respective top surfaces of the ILD 176, gate spacers 140, replacement gate structure(s) 170, S/D regions 164, or the like, may be substantially horizontal and/or may be substantially coplanar.

The illustrated semiconductor IC device 100 may be further fabricated by next forming a frontside contact ILD 176.1. The frontside contact ILD 176.1 may be formed upon respective top surfaces of replacement gate structure(s) 170, ILD 176, and gate spacers 140. The frontside contact ILD 176.1 may be formed by depositing a dielectric material, such as, for example, porous silicates, carbon doped oxides, silicon dioxides, silicon nitrides, silicon oxynitrides, or other dielectric materials. Any appropriate deposition technique for forming the frontside contact ILD 176.1 can be utilized. The frontside contact ILD 176.1 can be formed using, for example, CVD, PECVD, ALD, flowable CVD, spin-on dielectrics, or PVD.

The illustrated semiconductor IC device 100 may be further fabricated by next forming frontside contact 182 and frontside contact 184 within the frontside contact ILD 176.1. The frontside contact(s) 182, 184 may be formed by patterning respective frontside contact openings within frontside contact ILD 176.1 and/or ILD 176, respectively, from the frontside (e.g., from above the semiconductor IC device 100, as depicted, downward to respective structures thereof). The frontside contact(s) 182, 184 may be in direct or indirect physical and electrical contact and/or may physically meld with respective material(s) of one or more regions of the semiconductor IC device 100. For example, the illustrated frontside contact 182 is in direct contact with S/D region 164 of transistor 100.4 and the illustrated frontside contact 184 is in direct contact with S/D region 164 of transistor 100.10.

The frontside contact(s) 182, 184 may be formed by initially forming frontside contact opening(s). The frontside contact opening(s) may be formed by the same or shared lithography and etch process(es) or by sequential lithography and etch processes. In such process(es), a mask may be applied and patterned. An opening in the patterned mask may expose the portion of the underlying contact ILD 176.1 and/or ILD 176 to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

The frontside contact(s) 182, 184 may be further formed by depositing conductive material such as metal into the respective frontside contact opening(s). In an example, frontside contact(s) 182, 184 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, conductive fill. Subsequently, the respective top surfaces of frontside contact(s) 182, 184 and the frontside contact ILD 176.1 may be substantially horizontal and/or substantially coplanar. In embodiments, the frontside contact(s) 182, 184 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices.

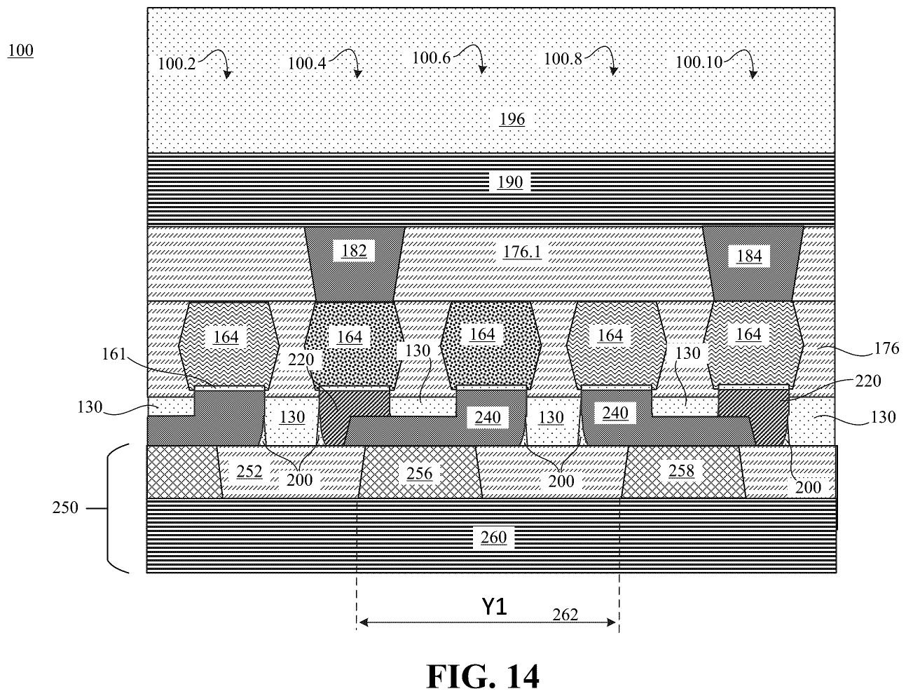

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 100. First, a frontside BEOL network 190 is formed on the frontside of the semiconductor device 100. Subsequently, a backside BEOL network 250, as depicted in FIG. 14, is formed.

In the depicted example, the frontside BEOL network 190 is formed over the contact ILD 176.1 and upon the frontside contact(s) 182, 184. Respective wires within the frontside BEOL network 190 may be electrically connected to the one or more S/D regions 164, one or more replacement gate structure(s) 170, or the like, by a respective frontside contact(s) 182, 184. For example, respective wire(s) within the frontside BEOL network 190 may be electrically connected to appropriate S/D regions 164 by frontside contact 182, and another and different group of respective wire(s) within the frontside BEOL network 190 may be electrically connected to appropriate replacement gate structures 170. In different implementations, the backside contacts 182, 184 may take the form of BEOL interconnects. In these implementations, respective wires within the frontside BEOL network 190 may be electrically connected to the one or more S/D regions 164, one or more replacement gate structure(s) 170, or the like, by a lowest BEOL interconnect, such as a vertical interconnect access (VIA), that is within the frontside BEOL network 190.

The frontside BEOL network 190 is located directly on the frontside surface of the MOL structure (e.g., contact ILD 176.1, frontside contact(s) 182, 184 etc.). The frontside BEOL network 190 can include one or more interconnect dielectric material layers (including one of the dielectric materials mentioned above for the frontside ILD 176) and contains metal wires (the metal wires can be composed of any electrically conductive metal or electrically conductive metal alloy) embedded therein. In some embodiments, the frontside metal wires within the frontside BEOL network 190 are composed of Cu. The frontside BEOL network 190 can include numbers of frontside metal levels, wherein “x” is an integer starting from 1. The frontside BEOL network 190 may further contain conductive pads that are connected to one or more of the metal wires and may be used to connect the semiconductor IC device 100 to an external and/or higher-level structure, such as a chip carrier, motherboard, or the like.

The illustrated semiconductor IC device 100 may be further fabricated by next bonding carrier wafer 196 to the frontside BEOL network 190. The carrier wafer 196 can include one of the semiconductor materials mentioned above for the semiconductor structure and the carrier wafer 196 may be attached to the semiconductor IC device 100 by a wafer-to-wafer bonding technique.

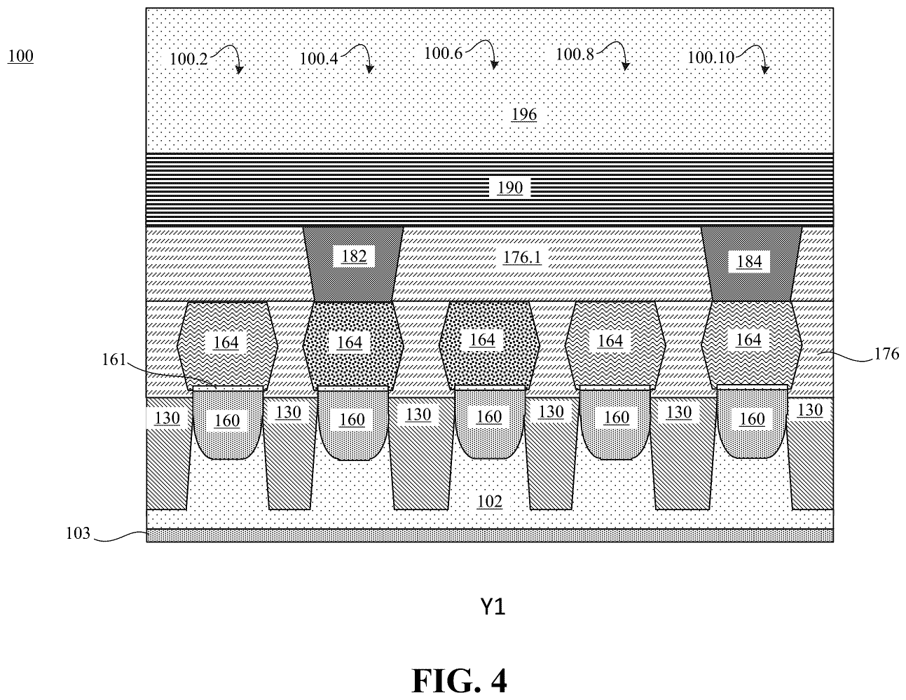

FIG. 4 depicts cross-sectional views of the semiconductor IC device 100 after fabrication operations, in accordance with embodiments of the present disclosure. In the depicted fabrication stages, the substrate structure may be recessed. For example, the lower substrate 101 may be removed.

The substrate structure may be recessed by flipping the semiconductor IC device 100 and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103.

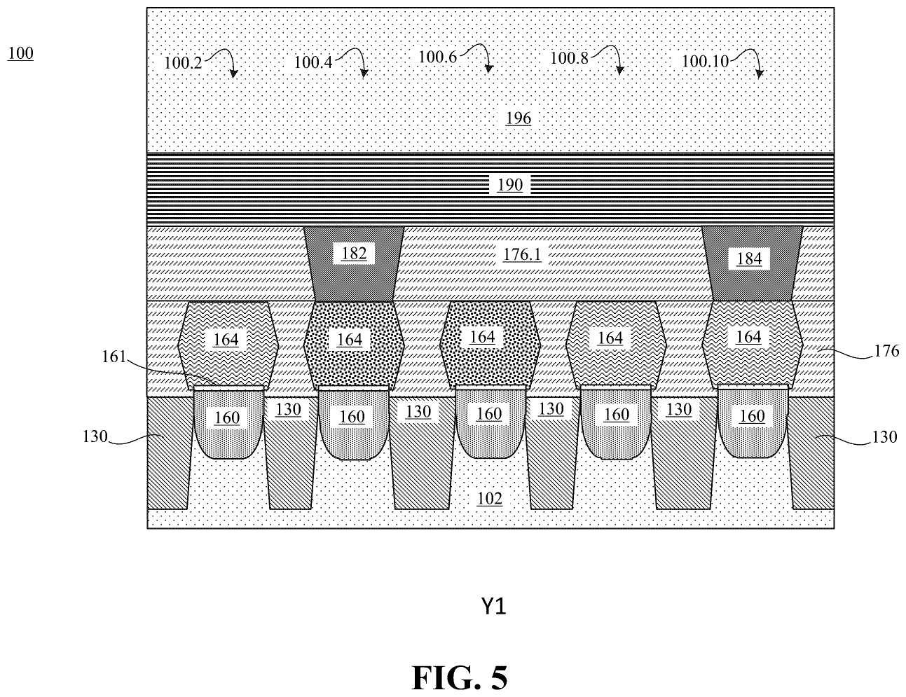

FIG. 5 depicts cross-sectional views of the semiconductor IC device 100 after fabrication operations, in accordance with embodiments of the present disclosure. In the depicted fabrication stages, the substrate structure may be further removed. For example, etch stop layer 103 may be removed.

The etch stop layer 103 may be removed by a subtractive removal technique such as a CMP, dry and/or wet etch. Upon removal of the etch stop layer 103, the bottom surface upper substrate 102 is exposed. The removal of etch stop layer 103 may be selective to the material of upper substrate 102. For example, etch stop layer 103 is removed by an etch that utilizes upper substrate 102 as the etch stop.

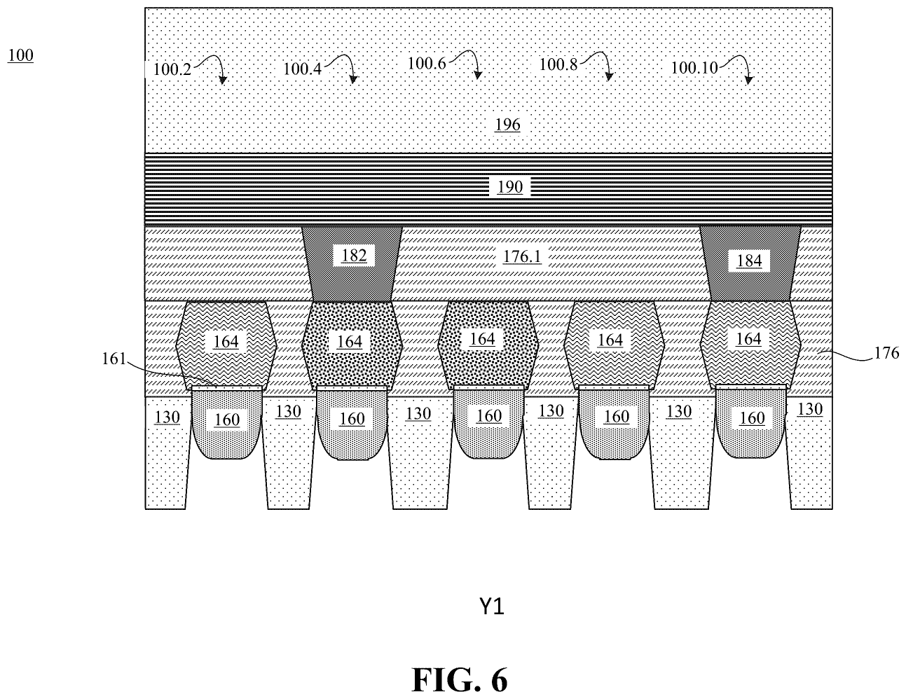

FIG. 6 depicts cross-sectional views of the semiconductor IC device 100 after fabrication operations, in accordance with embodiments of the present disclosure. In the depicted fabrication stages, the substrate structure may be further removed. For example, upper substrate 102 may be removed. The upper substrate 102 may be removed by an appropriate substrative removal technique, such as an etch, that removes associated portion(s) of the upper substrate 102. The etch may be timed or otherwise controlled to remove the material of substrate 102 selective to the STI regions 130, selective to the backside contact placeholders 160, selective to the bottom isolation, or the like.

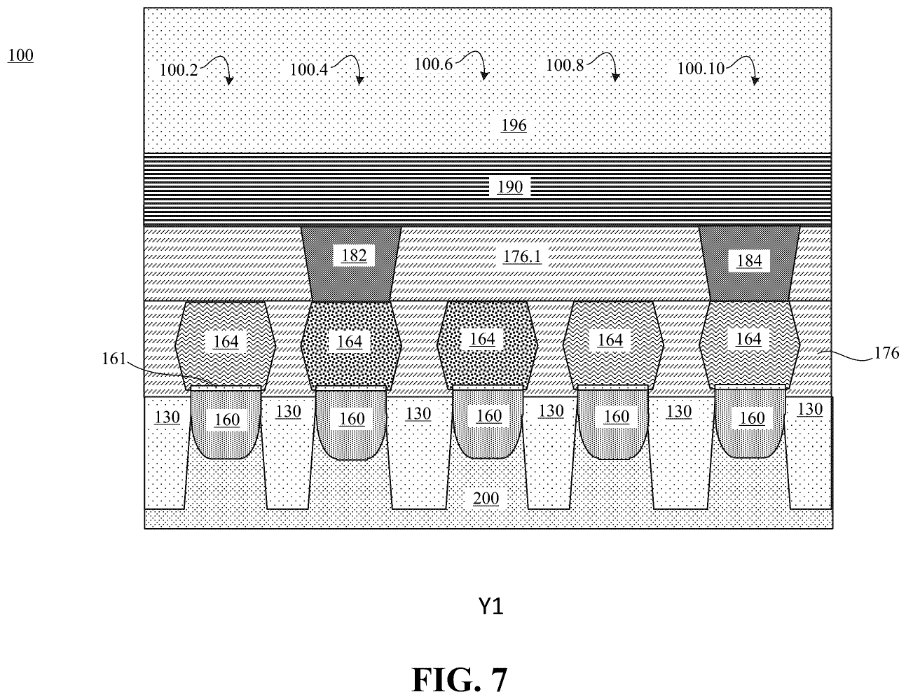

FIG. 7 depicts cross-sectional views of semiconductor IC device 100 shown after illustrative fabrication operation(s), in accordance with one or more embodiments. In the depicted fabrication stage, backside ILD 200 may be formed upon the exposed backside of the semiconductor IC device 100.

The backside ILD 200 may be formed upon the respective exposed backside surfaces of the STI regions 130, the backside contact placeholder(s) 160, the bottom isolation, and the like. The backside ILD 200 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 200 can be utilized. The backside ILD 200 can be formed using, for example, CVD, PECVD, ALD, flowable CVD, spin-on dielectrics, or PVD. In an example, the backside ILD 200 may be formed to a thickness below (as depicted) the bottom surface of the STI regions 130.

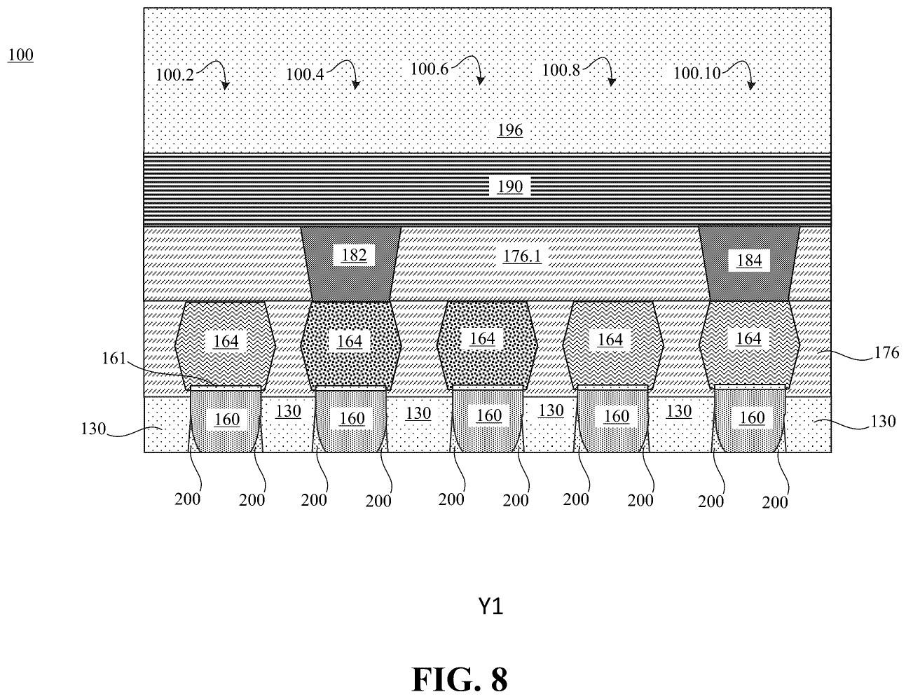

FIG. 8 depicts cross-sectional views of semiconductor IC device 100 shown after illustrative fabrication operation(s), in accordance with one or more embodiments. In the depicted fabrication stage, a planarization process, such as a CMP may planarize the backside surface of the semiconductor IC device 100. The CMP may create a substantially planar or substantially horizontal backside surface of the semiconductor IC device 100. In other words, the respective bottom surfaces of the STI regions 130, the backside ILD 200, and the backside contact placeholders 160, may be substantially coplanar and/or substantially horizontal.

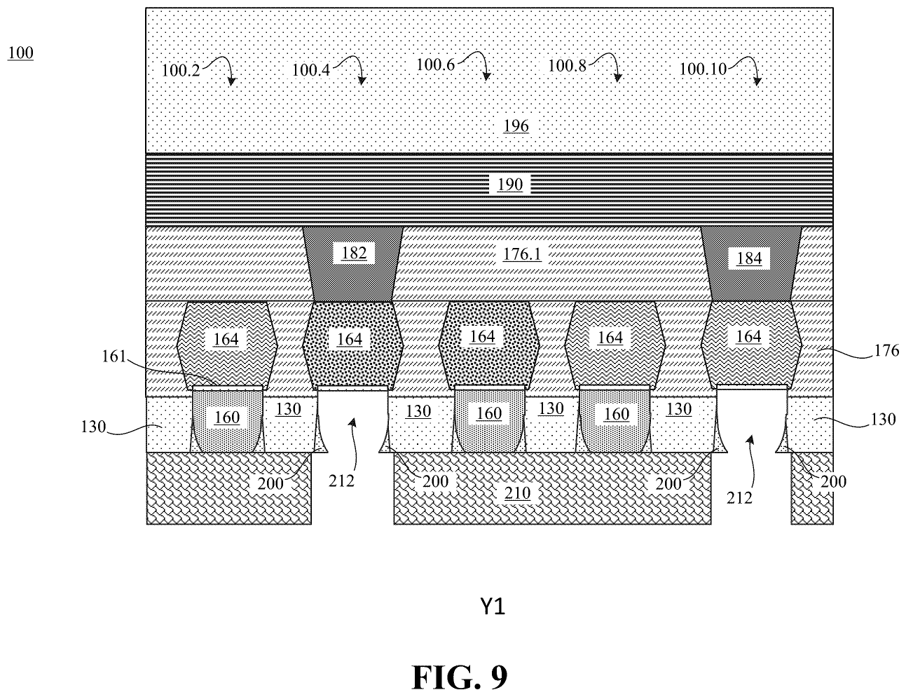

FIG. 9 depicts cross-sectional views of semiconductor IC device 100 shown after illustrative fabrication operation(s), in accordance with one or more embodiments. In the depicted fabrication stage, backside contact opening(s) 212 may be formed by removing selective backside contact placeholders 160.

The backside contact opening(s) 212 may be formed by the same or shared lithography and etch process(es), or sequential lithography and etch processes. In such process(es), a mask 210 may be applied to the backside of semiconductor IC device 100 and patterned. Openings in the patterned mask may expose the portions of the selected backside contact placeholders 160 to be removed while other protected portions of semiconductor IC device 100 may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention. For example, the backside contact opening 212 may formed by removing the appropriate backside contact placeholders 160 selective to the material of the etch stop layer 161, the backside ILD 200, or the like.

In one example, the entire applicable contact placeholder(s) 160 may be removed. In another example, the lower portion of the backside contact placeholder is removed using the etch stop layer 161 as an etch stop to protect the S/D region 164 there above. Optionally, at the present fabrication stage and as depicted, respective etch stop layer(s) 161 may also be removed thereby exposing at least a portion of the S/D region(s) 164 there above.

In an example, the backside contact placeholder(s) 160 may be selected as those backside contact placeholder(s) 160 that are associated with S/D region(s) 164 that are connected to the frontside BEOL network 190 by a frontside contact, such as frontside contacts 182, 184.

Further in the depicted fabrication stage, a backside contact preclean process, such as pre-silicide clean may clean the backside of the semiconductor IC device 100 which may partially, substantially, or fully remove backside ILD 200 (not shown) that are unprotected by the mask 210 and exposed by the backside contact opening(s) 212.

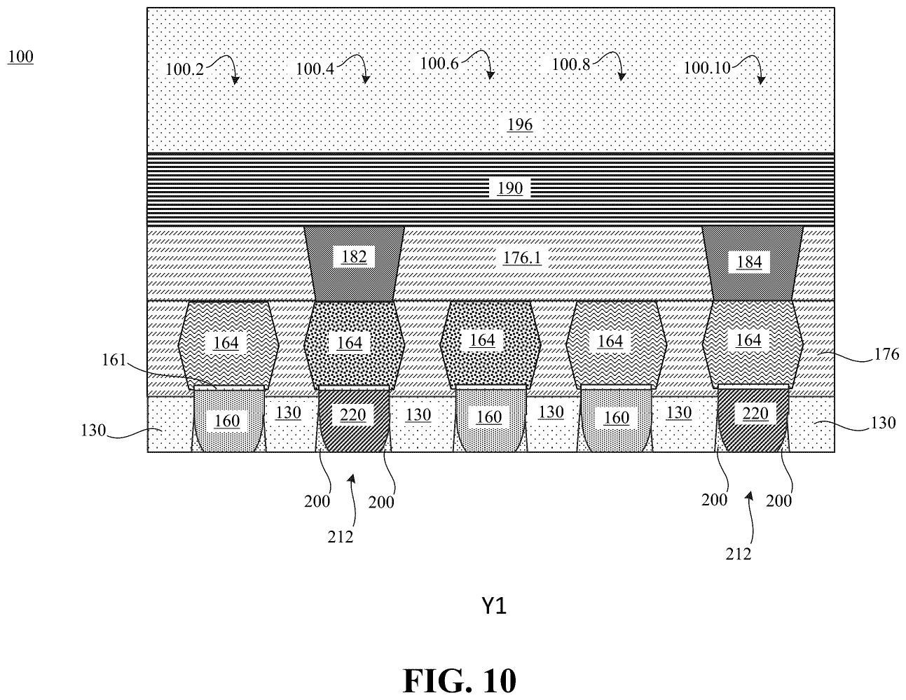

FIG. 10 depicts cross-sectional views of semiconductor IC device 100 shown after illustrative fabrication operation(s), in accordance with one or more embodiments. In the depicted fabrication stage, a replacement placeholder 220 may be formed within a respective backside contact opening 212.

The replacement placeholder(s) 220 may be formed by depositing a dielectric upon the respective exposed backside surfaces of the STI regions 130, the backside contact placeholder(s) 160, the backside ILD 200 (if present), or the like. The replacement placeholder 220 may be formed by depositing a dielectric material, such as, for example, porous silicates, carbon doped oxides, silicon dioxides, silicon nitrides, silicon oxynitrides, or other dielectric materials. Any appropriate deposition technique for forming the replacement placeholder(s) 220 can be utilized. The replacement placeholder(s) 220 can be formed using, for example, CVD, PECVD, ALD, flowable CVD, spin-on dielectrics, or PVD. In an example, the replacement placeholder(s) 220 may be formed to a thickness below (as depicted) the bottom surface of the STI regions 130 and subsequently planarized. For example, a CMP may planarize the backside surface of the semiconductor IC device 100. The CMP may create a substantially planar or substantially horizontal backside surface of the semiconductor IC device 100. In other words, the respective bottom surfaces of the STI regions 130, the backside ILD 200 (if present), the backside contact placeholders 160, and the replacement placeholder(s) 220 can may be substantially coplanar and/or substantially horizontal.

In some examples, the replacement placeholder(s) 220 are composed of a low-K dielectric material (a material with a lower dielectric constant relative to SiO₂) which may further contribute to adequately electrically isolating the extension region 248 of the backside contact 240, as depicted in FIG. 13, from the S/D region 164 there above. Therefore, the replacement placeholder(s) 220 may be composed of a different material relative to the material(s) of STI regions 130, backside ILD 200, or the like.

In an example, as depicted, in which portions of the backside ILD 200 are retained upon the sidewalls of respective STI regions 130, such portions of the backside ILD 200 may be between respective sidewalls of the STI regions 130 and the replacement placeholder(s) 220. In an example, as depicted, in which portions of the backside ILD 200 are retained upon the sidewalls of respective STI regions 130, the replacement placeholder 220 may have the substantially same geometry as the backside contact placeholder 160 that which was removed and replaced by the replacement placeholder 220. In another example, in which portions of the backside ILD 200 are not retained upon the sidewalls of respective STI regions 130, the replacement placeholder 220 may be between and be in contact with respective facing sidewalls of neighboring STI regions 130.

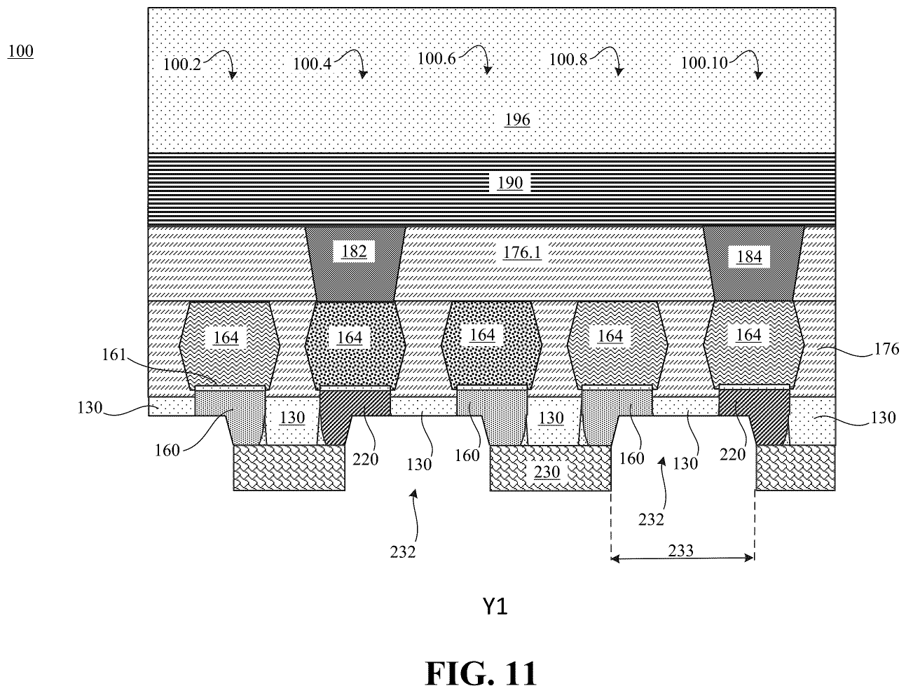

FIG. 11 depicts cross-sectional views of semiconductor IC device 100 shown after illustrative fabrication operation(s), in accordance with one or more embodiments. In the depicted fabrication stage, backside contact opening(s) 232 may be formed. The backside contact opening(s) 232 may be formed by the same or shared lithography and etch process(es), or sequential lithography and etch processes. In such process(es), a mask 230 may be applied to the backside of the semiconductor IC device 100 and patterned. Openings in the patterned mask may expose the portion(s) of the underlying STI region(s) 130, expose the backside ILD 200, expose the portion(s) of the underlying backside contact placeholder(s) 160, expose the portion(s) of the underling replacement placeholder(s) 220, and the like, to be removed while other protected portions of semiconductor IC device 100 may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

In the depicted example, the backside contact opening 232 may have a horizontal width 233 substantially the same as the pitch between S/D regions 164 and/or substantially the same as the pitch between backside contact placeholders 160, or the like. Further, the backside contact opening 232 may have a vertical depth, such that the well of the contact opening 232 may be located between the upper surface of the STI region(s) 130 and the lower surface of the STI region(s) 130 to adequately isolate the backside contact 240, depicted in FIG. 13, from the S/D region 164 there above. Similarly, the backside contact opening 232 may have a vertical depth, such that the well of the contact opening 232 may be located below the respective bottom surface(s) of the S/D regions 164 to prevent shorting between the backside contact 240, depicted in FIG. 13, and the S/D regions 164.

The backside contact opening 232 may be formed to expose the and/or to partially remove a portion of the appropriate backside contact placeholder 160 there above (e.g., the backside contact placeholder 160 that is below a S/D region 164 that is not connected to the frontside BEOL network 190). The backside contact opening 232 may be formed to expose the and/or to partially remove a portion of the appropriate replacement placeholder 220 there above (e.g., the replacement placeholder 220 that is adjacent to the backside contact placeholder 161 that is below the S/D region 164 that is not connected to the frontside BEOL network 190). The backside contact opening 232 may be further formed to expose the and/or to partially remove a portion of the appropriate STI region 130 there above (e.g., the STI region between that replacement placeholder 220 that backside contact placeholder 161).

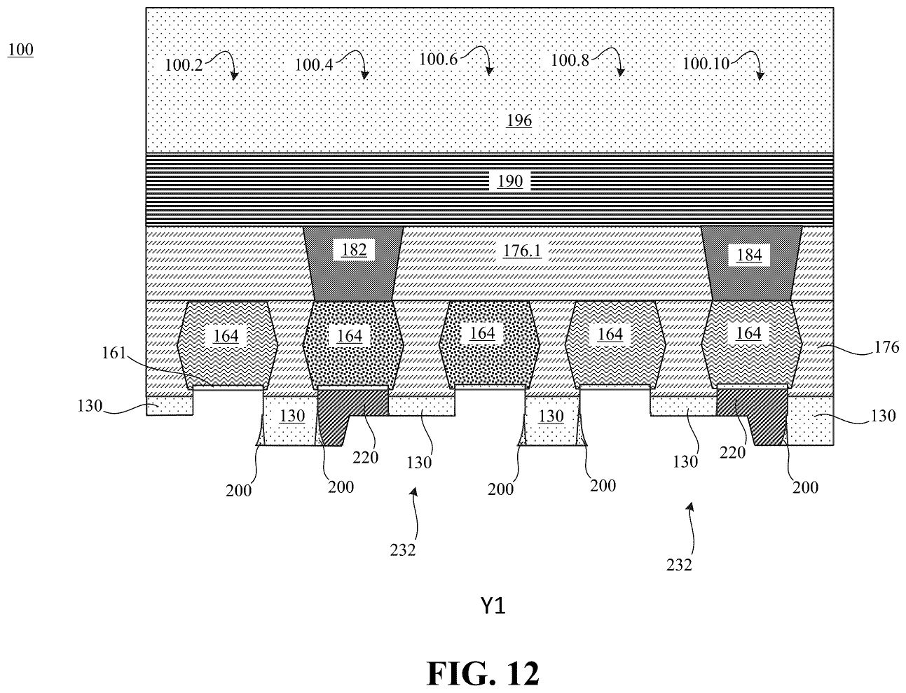

FIG. 12 depicts cross-sectional views of semiconductor IC device 100 shown after illustrative fabrication operation(s), in accordance with one or more embodiments. In the depicted fabrication stage, the backside contact placeholder(s) 160 (shown in FIG. 11) that are exposed by a respective backside contact opening(s) 232 may be removed.

The backside contact placeholder(s) 160 that are exposed by respective backside contact opening(s) 232 may be removed by a substrative removal technique, such as an etch. In one example, the entire applicable contact placeholder(s) 160 may be removed. In another example, the lower portion of the backside contact placeholder is removed using the etch stop layer 161 top surface of the backside contact placeholder 160 as an etch stop to protect the S/D region 164 there above. Optionally, at the present fabrication stage and as depicted, respective etch stop layer(s) 161 may also be removed thereby exposing at least a portion of the S/D region(s) 164 there above.

Optionally, the exposed S/D region(s) 164 may be gouged by a subtractive removal technique, such as an etch. In such process(es), dry and wet etching processes can have etching parameters that can be tuned, such as etchants used, etching temperature, etching solution concentration, etching pressure, source power, RF bias voltage, RF bias power, etchant flow rate, to promote desired S/D region(s) 164 material removal while also retaining the desired S/D region(s) 164. Optionally, a backside contact preclean process, such as pre-silicide clean may clean the backside of the semiconductor IC device 100 and may remove backside ILD 200.

FIG. 13 depicts cross-sectional views of semiconductor IC device 100 shown after illustrative fabrication operation(s), in accordance with one or more embodiments. In the depicted fabrication stage, a respective backside contact 240 may be formed within a respective backside contact opening 232. Further in the depicted fabrication stage, a planarization process, such as a CMP process or a mechanical grinding process, may remove excess portions of the backside contact(s) 240 may remove excess portions of STI region(s) 130, may remove excess portions of backside ILD 200 (if present), may remove excess portions of replacement placeholder(s) 220, and the like.

Respective backside contact(s) 240 may be formed within a respective backside contact opening 232 by depositing conductive material, such as metal, into the respective backside contact opening(s) 232. In an example, backside contact(s) 240 may be simultaneously formed by depositing a liner, such as Ni, NiPt or Ti, etc. onto the backside of semiconductor IC device 100 and into the backside contact opening(s) 232, depositing an adhesion liner, such as TiN, TaN, etc. upon the liner, and by depositing a conductive fill, such as Al, Ru, W, Co, Cu, etc. upon the adhesion liner.

Subsequently, a planarization process may expose a bottom surface (as depicted) of the STI region(s) 130. As a result, the respective bottom surfaces of backside contact(s) 240, STI region(s) 130, replacement placeholder(s) 220, and backside ILD 200 (if present) may be substantially horizontal and/or substantially coplanar.

The backside contact(s) 240 may include an inline region 246 and an extension region 248. The extension region 248 extends from the inline region 246 substantially horizontally toward an adjacent S/D region 164 that is connected to the frontside BEOL network 190 by a frontside contact, such as frontside contact 182, 184. As a result of the width 233 of the backside contact opening 232 that forms the backside contact 240, the extension region 248 may include a sidewall that is substantially inline with a vertical bisector of the adjacent S/D region 164, of the replacement placeholder 220 underneath the adjacent S/D region 164, or the like. In this manner, the extension region 248 includes a portion that is inset within and underneath the adjacent S/D region 164.

In an example, as depicted, in which portions of the backside ILD 200 are retained upon the sidewalls of respective STI regions 130, such portions of the backside ILD 200 may be between respective sidewalls of the STI regions 130 and the backside contact 240. In an example, as depicted, the inline region 246 may have the substantially same geometry as the backside contact placeholder 160 that which was removed. In another example, in which portions of the backside ILD 200 are not retained upon the sidewalls of respective STI regions 130, the inline region 246 of backside contact 240 may be in contact a sidewall of STI region 130.

FIG. 14 depicts cross-sectional views of semiconductor IC device 100 shown after illustrative fabrication operation(s), in accordance with one or more embodiments. In the depicted fabrication stage, a backside BEOL network 250 may be formed.

The backside BEOL network 250 may be formed over the backside ILD 200 (if present), over backside contact(s) 240, over STI region(s) 130, and the like. The backside BEOL network 250 may be indirectly electrically and/or indirectly physically connected to the one or more S/D regions 164 by way of a particular backside contact(s) 240. For example, as illustrated, a backside wire 256 (e.g., a backside power wire, backside power rail, etc.) within the backside BEOL network 250 may be connected the backside contact 240 of transistor 100.6. Similarly, a second backside wire 258 (e.g., a backside power wire, backside signal wire, backside power rail, etc.) within the backside BEOL network 250 may be connected to a S/D region 164 via backside contact 240 of transistor 100.8.

The backside BEOL network 250 can include one or more interconnect dielectric material layers (such as layer 252 which may be composed of one or more of the dielectric materials mentioned above for the ILD 176) and contains backside conductive wires and/or interconnects, such as VIAs, embedded therein. Additional layers and/or levels of such dielectric material and metal layers are depicted as backside BEOL layers 260. In some embodiments, the backside wires within the backside BEOL network 250 are composed of Cu. The backside BEOL network 250 can include “x” numbers of backside metal levels, wherein “x” is an integer starting from 1. If not included in frontside BEOL network 190, backside BEOL network 250 may further contain conductive pads that are connected to one or more of the backside metal wires and may be used to connect the semiconductor IC device 100 to the external and/or higher-level structure.

In an example, signal routing and power routing is effectively split between the frontside BEOL network 190 and the backside BEOL network 250. For example, at least 90% of the frontside metal wires (e.g., furthest from the transistors 100.2, 100.4, 100.6, 100.8, and 100.10) are signal routing metal wires and the remainder frontside metal wires which are usually present in metal levels closest to the transistors, can be used as power routing wires. Further in this example, at least 90% of the backside metal wires that are in metal levels closest to the transistors 100.2, 100.4, 100.6, 100.8, and 100.10 are power routing metal wires and the remainder backside metal wires which are usually present in metal levels furthest away from the transistors 100.2, 100.4, 100.6, 100.8, and 100.10, can be used as signal routing wires. Power routing wires may be less dense than signal routing wires. A signal routing wire is defined herein as a conductive feature, such as a wire, interconnect, or the like, that is configured to electrically carry a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like. For clarity, in some examples, the backside BEOL network 250 may be a backside power distribution network (BSPDN).

The backside BEOL network 250 includes various wiring levels. The wiring levels may alternate between a VIA level and a metal level. To form a VIA level, an associated dielectric passivation layer may be formed, the dielectric passivation layer may be patterned to create a VIA opening therein, and conductive or metal material may be deposited within the VIA opening to form a via contact.

To form a metal level, an associated dielectric layer, such as layer 252, may be formed, the dielectric layer may be patterned to create a wiring trench therein, and conductive or metal material may be deposited within the wiring trench to form a wire and/or a VIA. A wire, such as within a lowest metal level may connect directly one or more VIAs or backside contact(s) 204.

For clarity, the backside BEOL network 250 may include adjacent wires 256, 258. The respective extension regions 248 (shown in FIG. 13) may provide for relatively increased surface area for an interface between the backside contact 240 and the backside wires 256, 258, respectively. This relatively larger interfacial area may relatively decrease the interfacial resistance therebetween and may ease alignment complexities of the backside wire wires 256, 258 landing against the backside contact 240, respectively. The respective extension regions 248 may further allow for relatively increased distance or pitch 262 between adjacent backside wires 256, 258 of the backside BEOL network 250, which may reduce the propensity of shorting between the adjacent backside wires 256 and 258. For example, the relatively increased pitch 262 provides for increased isolative material, such as dielectric material of layer 252, between adjacent backside wires 256 and 258.

For further clarity, an etch stop layer 161 may be between the backside contact 240 and the S/D region 164. The etch stop layer 161 may be raised such that the bottom surface of the etch stop layer 161 is above a top surface of the STI region(s) 130. The replacement placeholder 220 may be self-aligned with respect to the S/D region 164 there above and may be confined by at least adjacent STI regions 130.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

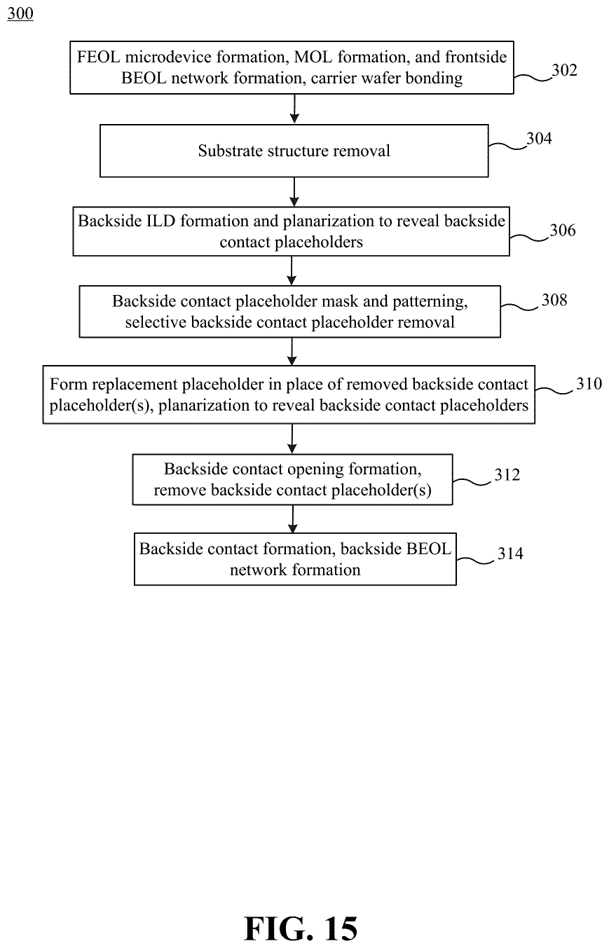

FIG. 15 depicts a flow diagram illustrating a method 300 to fabricate a semiconductor IC device, such as semiconductor IC device 100. The depicted fabrication operations of method 300 are illustratively depicted and described above with reference to one or more of FIG. 3 through FIG. 14 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming one or more front end of line (FEOL) microdevices, such as transistors, with forming middle of line (MOL) structures, such as frontside contact(s), with forming a frontside back end of line (BEOL) network, and with attaching a carrier wafer thereto. For example, one or more transistors, such as transistors 100.2, 100.4, 100.6, 100.8, and 100.10, are formed, one or more frontside contacts 182, 184 are formed that may contact components or regions (such as S/D regions 164) of transistors 100.4, 110.10, the frontside BEOL network 190 is formed upon the one or more frontside contacts, and a carrier wafer 196 is bonded to the frontside BEOL network 190.

At block 304, the semiconductor IC device may be flipped, and a substrate associated with the FEOL microdevices may be removed. For example, the lower substrate 101 of the substrate structure may be removed, the etch stop layer 103 of the substrate structure may be removed, and the upper substrate 102 of the substrate structure may be removed.

At block 306, method 300 may continue with forming a backside ILD and planarizing the backside ILD to reveal backside contact placeholders that are associated with microdevices. For example, the backside ILD 200 may be deposited over the backside placeholders 160, over STI region(s) 130, or the like. Subsequently, the ILD 200 may be planarized such that the backside placeholders 160 are exposed. The planarization of the semiconductor IC device 100 may create a substantially horizontal and/or substantially coplanar backside surface of the semiconductor IC device 100.

At block 308, method 300 may further continue with backside contact placeholder mask and patterning and with selective backside contact placeholder removal. For example, mask 210 is formed upon the backside of the semiconductor IC device 100 and is patterned to form backside contact opening(s) 212 so that selected backside contact placeholder 160 are removed. The selected backside contact placeholders 160 may be those selected backside contact placeholders 160 that are directly underneath S/D regions 164 that are connected to the frontside BEOL network 190.

At block 310, method 300 may continue with forming replacement placeholder within the cavity of the removed backside contact placeholder and with planarizing the backside of the semiconductor IC device to again reveal the existing backside contact placeholder(s). For example, a replacement placeholder 220 is formed within backside contact opening 212 in place of the removed backside contact placeholder 160. If replacement placeholder 220 is formed as a blanket material, the backside of the semiconductor IC device 100 may be planarized to again reveal the existing backside contact placeholder(s) 160.

At block 312, method 300 may continue with backside contact opening formation and within removing the backside contact placeholder(s) that are exposed by a respective backside contact opening. For example, backside contact opening(s) 232 may be formed within the STI region(s) 130, within the backside ILD 200, within backside contact placeholder(s) 160, and/or within the replacement placeholders 220, or the like. The backside contact placeholder(s) 160 that are exposed by the backside contact opening(s) 232 may subsequently be removed.

At block 314, method 300 may further continue with forming a backside contact within a respective backside contact opening and with forming a backside BEOL network over the backside contact(s). For example, a backside contact 240 may be formed within a particular backside opening 232. Subsequently, a CMP process may remove excess backside contact material and a backside BEOL network 250 may be formed upon the planarized backside of semiconductor IC device 100.

For clarity, method 300 includes forming a first backside contact placeholder and a second backside contact placeholder (e.g., accomplished in the FEOL microdevice fabrication stages of FIG. 3). Method 300 further includes forming a first source/drain (S/D) region upon the first backside contact placeholder and forming a second S/D region upon the second backside contact placeholder (e.g., accomplished in the FEOL microdevice fabrication stages of FIG. 3). Method 300 further includes removing the first backside contact placeholder while retaining the second backside contact placeholder (e.g., depicted for example in FIG. 9 where some backside contact placeholders 160 are removed while others are retained). Method 300 further includes forming a replacement placeholder in place of the removed first backside contact placeholder (e.g., depicted in FIG. 10 wherein replacement placeholder 120 is formed in place of the removed backside contact placeholders 160). Method 300 further includes forming a backside contact opening within the replacement placeholder and by removing the second backside contact placeholder (e.g., depicted in FIG. 11 and in FIG. 12 with the formation of the backside contact openings 232 and the removal of the backside contact placeholders 160 exposed thereby). Method 300 further includes forming a backside contact within the backside contact opening (e.g., depicted in FIG. 13 by the formation of backside contacts 240).

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a backside back end of line (BEOL) network comprising a backside wire;
a first transistor comprising a first source/drain (S/D) region and a replacement placeholder below the first S/D region; and
a second transistor comprising a second S/D region and a backside contact connected to and below the second S/D region, the backside contact comprising an extension region between the backside wire and the replacement placeholder.

2. The semiconductor IC device of claim 1, wherein the first transistor and the second transistor are in a same transistor cell.

3. The semiconductor IC device of claim 1, wherein the first S/D region and the second S/D region are directly adjacent.

4. The semiconductor IC device of claim 1, wherein the backside wire is directly connected to the extension region.

5. The semiconductor IC device of claim 1, wherein the backside contact further comprises:
an inline region that is substantially inline with and below the second S/D region and from which the extension region horizontally extends toward the replacement placeholder.

6. The semiconductor IC device of claim 1, wherein the replacement placeholder electrically isolates the extension region from the first S/D region.

7. The semiconductor IC device of claim 1, further comprising:
a frontside BEOL network; and
a frontside contact that connects the first S/D region to the frontside BEOL network.

8. The semiconductor IC device of claim 5, wherein the first transistor comprises a first etch stop between the first S/D region and the replacement placeholder and wherein the second transistor comprise a second etch stop between the second S/D region and the inline region.

9. The semiconductor IC device of claim 5, wherein a shallow trench isolation (STI) region is between the inline region and the replacement placeholder.

10. A semiconductor integrated circuit (IC) device comprising:
a first transistor and a second transistor;
the first transistor comprising a first source/drain (S/D) region and a first backside contact connected to and below the first S/D region, the first backside contact comprising a first inline region and a first extension region extending from the first inline region horizontally away from the second transistor; and
the second transistor comprising a second S/D region and a second backside contact connected to and below the second S/D region, the second backside contact comprising a second inline region and a second extension region extending from the second inline region horizontally away from the first transistor.

11. The semiconductor IC device of claim 10, wherein the first transistor is a pFET and the second transistor is an nFET.

12. The semiconductor IC device of claim 10, wherein an interlayer dielectric (ILD) is between sidewall(s) of the first S/D region and sidewall(s) of the second S/D region.

13. The semiconductor IC device of claim 10, further comprising:
a backside back end of line (BEOL) network comprising a first backside wire below and connected to the first extension region and a second backside wire below and connected to the second extension region.

14. The semiconductor IC device of claim 10, wherein the first inline region is substantially inline with and below the first S/D region and wherein the second inline region is substantially inline with and below the second S/D region.

15. The semiconductor IC device of claim 13, wherein a pitch between the first backside wire and the second backside wire is greater than a pitch between the first S/D region and the second S/D region.

16. The semiconductor IC device of claim 13, wherein a pitch between the first backside wire and the second backside wire is greater than a pitch between the first inline region and the second inline region.

17. The semiconductor IC device of claim 10, wherein the first transistor comprises a first etch stop between the first S/D region and the first inline region and wherein the second transistor comprises a second etch stop between the second S/D region and the second inline region.

18. The semiconductor IC device of claim 10, wherein a shallow trench isolation (STI) region is between the first inline region and the second inline region.

19. A semiconductor integrated circuit (IC) device fabrication method comprising:
forming a first backside contact placeholder and a second backside contact placeholder;
forming a first source/drain (S/D) region upon the first backside contact placeholder and forming a second S/D region upon the second backside contact placeholder;
removing the first backside contact placeholder while retaining the second backside contact placeholder;
forming a replacement placeholder in place of the removed first backside contact placeholder;
forming a backside contact opening within the replacement placeholder and by removing the second backside contact placeholder; and
forming a backside contact, that includes an extension region, within the backside contact opening.

20. The semiconductor IC device fabrication method of claim 19, wherein the backside contact comprises an inline region below the second S/D region and wherein the extension region extends from the inline region such that a section of the extension region is surrounded by the replacement placeholder.
